(19) United States
(12) Patent Application Publication
(10) Pub. No.: US 2026/0331729 A1
(43) Pub. Date: Oct. 22, 2026

(54) BATTERY PACK INCLUDING AN OVERCHARGE PROTECTION CIRCUIT

(71) Applicant: MILWAUKEE ELECTRIC TOOL CORPORATION, Brookfield, WI (US)

(72) Inventor: Mayada I. Issa, Milwaukee, WI (US)

(21) Appl. No.: 19/648,422

(22) Filed: Apr. 15, 2026

Related U.S. Application Data
(60) Provisional application No. 63/790,283, filed on Apr. 17, 2025.

(51) Int. Cl. H01M 50/583; G01R 31/3835; G01R 31/396; H01M 10/48

(52) U.S. Cl. CPC H01M 50/583; G01R 31/3835; G01R 31/396; H01M 10/482

(57) ABSTRACT

A battery pack including a plurality of battery cells, a protection circuit, a first switch, and a second switch. The protection circuit is connected to the plurality of battery cells. The protection circuit is configured to monitor a voltage of each of the plurality of battery cells, compare the voltage of each of the plurality of battery cells to a threshold voltage, and output a protection signal in response to the voltage of at least one of the plurality of battery cells being greater than or equal to the threshold voltage. The first switch is connected to the protection circuit. The first switch is configured to receive the protection signal. The second switch is connected to the first switch and the plurality of battery cells. A conductive state of the second switch is controlled by the first switch.

### RELATED APPLICATIONS

This application claims the benefit of U.S. Provisional Patent Application No. 63/790,283, filed Apr. 17, 2025, the entire content of which is hereby incorporated by reference.

### FIELD

Embodiments described herein relate to battery packs.

### SUMMARY

Embodiments described herein provide overcharge protection for battery packs, such as battery packs that have shared charge and discharge paths. It is sometimes desirable to charge battery packs with high charge currents (e.g., 40 Amps). While charging at such high currents, battery packs can experience an overcharge condition (e.g., overvoltage). When battery packs are using the same current path for both charging and discharging and an overcharge condition is present, the battery pack needs to be able to stop the charging. Battery packs described herein provide overcharge protection that permits the battery packs to have full discharge capabilities while also protecting the battery packs during charging.

Battery packs described herein include a plurality of battery cells, a protection circuit, a first switch, and a second switch. The protection circuit is connected to the plurality of battery cells. The protection circuit is configured to monitor a voltage of each of the plurality of battery cells, compare the voltage of each of the plurality of battery cells to a threshold voltage, and output a protection signal in response to the voltage of at least one of the plurality of battery cells being greater than or equal to the threshold voltage. The first switch is connected to the protection circuit. The first switch is configured to receive the protection signal. The second switch is connected to the first switch and the plurality of battery cells. A conductive state of the second switch is controlled by the first switch.

In some aspects, the first switch is configured to be switched ON in response to receiving the protection signal.

In some aspects, the second switch is configured to be switched OFF in response to the first switch being switched ON.

In some aspects, when the second switch is switched OFF, the second switch prevents charging of the plurality of battery cells.

In some aspects, the first switch is configured to be switched OFF in response to the protection circuit not outputting the protection signal.

In some aspects, the protection circuit is configured to not output the protection signal when the voltage of each of the plurality of battery cells is less than the threshold voltage.

In some aspects, the first switch is connected between the plurality of battery cells and a power terminal of the battery pack.

In some aspects, when the first switch is switched ON, charging current is permitted to pass from the power terminal of the battery pack to the plurality of battery cells.

Battery packs described herein include a plurality of battery cells, a protection circuit, a switch, and a fuse. The protection circuit is connected to the plurality of battery cells. The protection circuit is configured to monitor a voltage of each of the plurality of battery cells, compare the voltage of each of the plurality of battery cells to a threshold voltage, and output a protection signal in response to the voltage of at least one of the plurality of battery cells being greater than or equal to the threshold voltage. The switch is connected to the protection circuit. The switch is configured to receive the protection signal. The fuse is connected to the switch and the plurality of battery cells. The fuse is controlled by the switch.

In some aspects, the fuse is further connected to a connector terminal, wherein the connector terminal is configured to provide charging current to the plurality of battery cells.

In some aspects, the connector terminal is a charge terminal of the battery pack.

In some aspects, the charge terminal is disconnected from the plurality of battery cells when the fuse is opened.

In some aspects, the fuse is a resettable fuse.

In some aspects, the fuse is a one-time, non-resettable fuse.

In some aspects, the switch is configured to be switched ON in response to the protection circuit outputting the protection signal.

In some aspects, the protection circuit is configured to not output the protection signal when the voltage of each of the plurality of battery cells is less than the threshold voltage.

Battery packs described herein include a plurality of battery cells, a protection circuit, an optocoupler, and a switch. The protection circuit is connected to the plurality of battery cells. The protection circuit is configured to monitor a voltage of each of the plurality of battery cells, compare the voltage of each of the plurality of battery cells to a threshold voltage, and output a protection signal in response to the voltage of at least one of the plurality of battery cells being greater than or equal to the threshold voltage. The optocoupler is connected to the protection circuit. The optocoupler is configured to receive the protection signal. The switch is connected to the optocoupler and the plurality of battery cells. A conductive state of the switch is controlled by the optocoupler.

In some aspects, the switch is configured to be switched OFF when the optocoupler receives the protection signal.

In some aspects, the switch is configured to be switched ON in response to the protection circuit not outputting the protection signal.

In some aspects, the protection circuit is configured to not output the protection signal when the voltage of each of the plurality of battery cells is less than the threshold voltage.

Before any embodiments are explained in detail, it is to be understood that the embodiments are not limited in application to the details of the configurations and arrangements of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other aspects of the embodiments will become apparent by consideration of the detailed description and accompanying drawings.

### BRIEF DESCRIPTION OF THE DRAWINGS

FIG. 1 is a side view of a power tool, according to some embodiments.

FIG. 2 is a block diagram illustrating a control system for the power tool of FIG. 1, according to some embodiments.

FIG. 3 is a perspective view of a battery pack, according to some embodiments.

FIG. 4 is an exploded view of the battery pack of FIG. 3, according to some embodiments.

FIG. 5 is a top view of the battery pack of FIG. 3, according to some embodiments.

FIG. 6 is a schematic block diagram illustrating a protection circuit for a battery pack, according to some embodiments.

FIG. 7 is a schematic block diagram illustrating a protection circuit for a battery pack using an optocoupler, according to some embodiments.

FIG. 8 is a schematic block diagram illustrating of a protection circuit for a battery pack using a fuse, according to some embodiments.

FIG. 9 illustrates a time diagram of power tool performance, according to some embodiments.

FIG. 10 is a flow chart illustrating a method for determining overcharge conditions of a battery pack, according to some embodiments.

### DETAILED DESCRIPTION

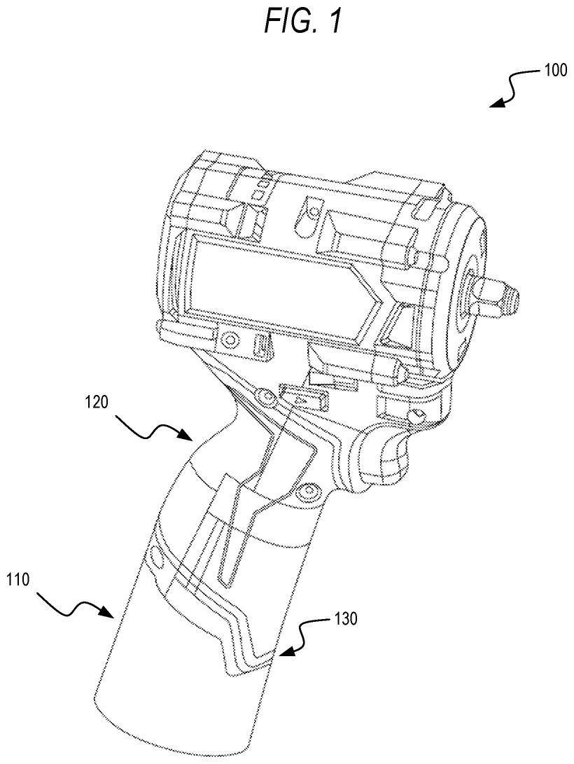

FIG. 1 illustrates a power tool 100. The power tool 100 is in the form of a rotary impact tool. In other embodiments, the power tool 100 may include drills, circular saws, jig saws, band saws, reciprocating saws, screw drivers, angle grinders, straight grinders, hammer drills, multi-tools, rotary hammers, angle drills, powered ratchets, powered torque wrenches, hydraulic pulse tools, hydraulic tensioning tools, lock bolt installation tools, reaction arm tools, riveting tools, nailers, staplers, TC bolt guns, portable power source that converts battery power to AC output using an inverter, and the like.

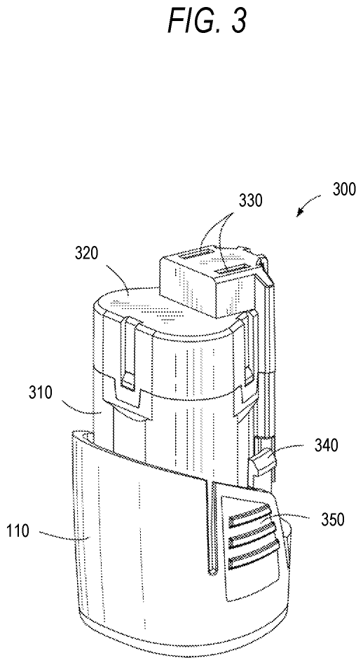

The power tool 100 including a handle 120. The handle 120 includes a battery pack receptacle 130. The battery pack receptacle 130 is configured to receive a battery pack 300 (shown in FIG. 3). The battery pack 300 includes a battery pack housing 110. The battery pack receptacle 130 is configured to couple to the battery pack housing 110.

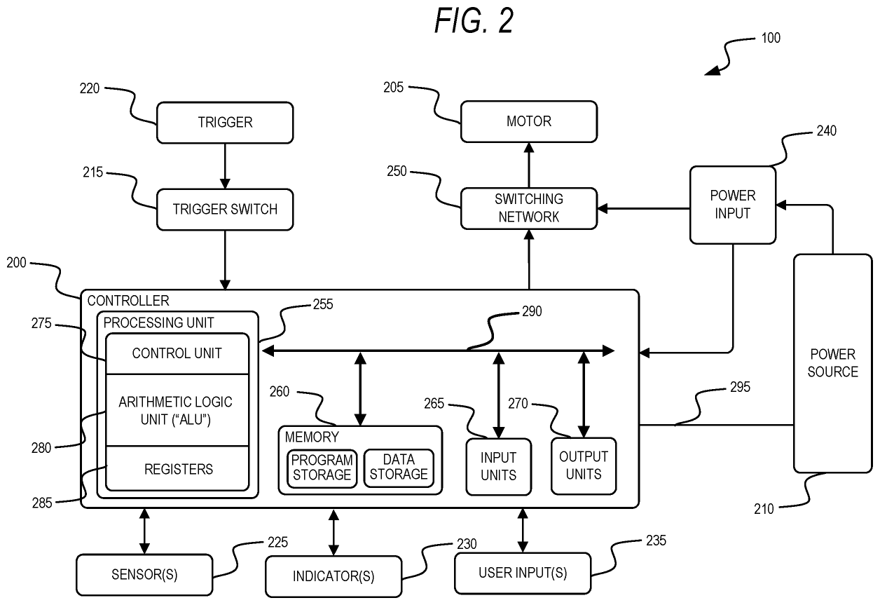

FIG. 2 is a simplified block diagram of a control system of the power tool 100 of FIG. 1, according to some embodiments. The control system includes a controller 200. The controller 200 is electrically and/or communicatively connected to a variety of modules or components of the power tool 100. For example, the illustrated controller 200 is electrically connected to a power source 210 (e.g., battery pack 300 through battery pack receptacle 130), a trigger switch 215 (connected to a trigger 220 [e.g., a variable speed trigger]), one or more sensors or sensing circuits 225, one or more indicators 230, a user input module 235, a power input module 240, and a power switching network 250. The controller 200 includes combinations of hardware and software that are operable to, among other things, control the operation of the power tool 100, monitor the operation of the power tool 100 using, for example, the one or more sensors or sensing circuits 225, activate the one or more indicators 230 (e.g., an LED), and/or the like.

The controller 200 includes a plurality of electrical and electronic components that provide power, operational control, and protection to the components and modules within the controller 200 and/or the power tool 100. For example, the controller 200 includes, among other things, a processing unit 255 (e.g., a microprocessor, a microcontroller, an electronic processor, an electronic controller, or another suitable programmable device), a memory 260, input units 265, and output units 270. The processing unit 255 includes, among other things, a control unit 275, an arithmetic logic unit (“ALU”) 280, and a plurality of registers 285, and is implemented using a known computer architecture (e.g., a modified Harvard architecture, a von Neumann architecture, etc.). The processing unit 255, the memory 260, the input units 265, and the output units 270, as well as the various modules or circuits connected to the controller 200 are connected by one or more control and/or data buses (e.g., common bus 290). The control and/or data buses are shown generally in FIG. 3 for illustrative purposes. The use of one or more control and/or data buses for the interconnection between and communication among the various modules, circuits, and components would be known to a person skilled in the art.

The memory 260 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 255 is connected to the memory 260 and executes software instructions that are capable of being stored in a RAM of the memory 260 (e.g., during execution), a ROM of the memory 260 (e.g., on a generally permanent basis), or another non-transitory computer readable medium such as another memory or a disc. Software included in the implementation of the power tool 100 can be stored in the memory 260 of the controller 200. The software includes, for example, firmware, one or more applications, program data, filters, rules, one or more program modules, and other executable instructions. The controller 200 is configured to retrieve from the memory 260 and execute, among other things, instructions related to the control processes and methods described herein. In other constructions, the controller 200 includes additional, fewer, or different components.

In some embodiments, the power tool 100 includes a battery pack interface (e.g., battery pack receptacle 130) including a combination of mechanical components (e.g., rails, grooves, latches, etc.) and electrical components (e.g., one or more terminals) configured to and operable for interfacing (e.g., mechanically, electrically, and communicatively connecting) the power tool 100 with the power source 210 (e.g., the battery pack 300). For example, power provided by the battery pack 300 to the power tool 100 is provided through the battery pack interface to the power input module 240. The power input module 240 includes combinations of active and passive components to regulate or control the power received from the battery pack 300 prior to power being provided to the controller 200. The battery pack interface also supplies power via the power input module 240 to the power switching network 250 to provide power to the motor 205. The battery pack interface also includes, for example, a communication line 295 for providing a communication line or link between the controller 200 and the power source 210.

The indicators 230 include, for example, one or more light-emitting diodes (“LEDs”). The indicators 230 can be configured to display conditions of, or information associated with, the power tool 100. For example, the indicators 230 are configured to indicate measured electrical characteristics of the power tool 100, the status of the power tool 100, etc. The user input module 235 is operably coupled to the controller 200 to, for example, select a forward mode of operation or a reverse mode of operation, a torque and/or speed setting for the power tool 100 (e.g., using torque and/or speed switches), etc. In some embodiments, the user input module 235 includes a combination of digital and analog input or output devices required to achieve a desired level of operation for the power tool 100, such as one or more knobs, one or more dials, one or more switches, one or more buttons, etc. Although illustrated separately, the trigger switch 215 and/or the trigger 220 may be a part of the user input module 235.

The power switching network 250 provides operating power to the motor 205 based on control signals from a motor controller, such as the controller 200. The power switching network 250 includes a plurality of electronic switches (e.g., FETs, bipolar junction transistors, and the like) connected to form a network that controls the activation of the motor 205 based on pulse-width modulated (PWM) signals. The power switching network 250 may be implemented as an inverter (e.g., a three-phase inverter bridge). For instance, the power switching network 250 may receive PWM signals from the controller 200 to drive the motor 205. Generally, when the trigger 220 is depressed, electrical current is supplied from the power source 210 to the motor 205 via the power switching network 250. When the trigger 220 is not depressed, electrical current is not supplied from the power source 210 to the motor 205. For example, a trigger pull sensor senses the amount that the trigger 220 is pulled.

The motor 205 may be energized based on a state of the trigger 220. Generally, when the trigger 220 is activated, the motor 205 is energized, and when the trigger 220 is deactivated, the motor 205 is de-energized. In the illustrated embodiment, the trigger 220 may be biased (e.g., with a biasing member such as a spring) such that the trigger 220 moves in a second direction away from the handle of the power tool 100 when the trigger 220 is released by the user. In some embodiments, the controller 200 determines a shutdown condition of the power tool 100 based on the trigger pull sensor. For example, the controller 200 may determine that the power tool 100 is no longer being operated based on a lack of input from the trigger pull sensor and/or a release of the trigger 220 for a predetermined amount of time. In some examples, the trigger 220 is a variable speed trigger such that the trigger switch 215 provides a signal to the controller 200 corresponding to the amount of trigger pull (e.g., the distance to which the trigger is pulled). This signal from the trigger switch 215 may be generated using, for example, a potentiometer, an inductive sensor, a magnetic sensor, or the like, and provides a speed command (e.g., as a percentage of maximum speed).

The power switching network 250 is electrically connected to the motor 205. In some embodiments, the motor 205 is a brushless DC (BLDC) motor. In some embodiments, the motor 205 is a permanent magnet synchronous motor (PMSM). In some embodiments, the power source 210 is a battery pack, such as the battery pack 300. The power switching network 250 is also electrically and communicatively connected to the controller 200.

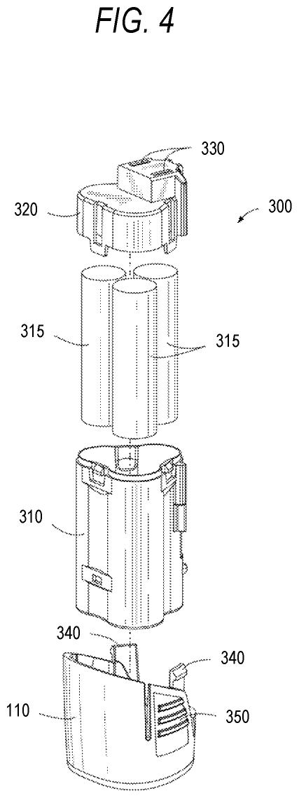

FIG. 3 illustrates the battery pack 300. The battery pack 300 includes the battery pack housing 110 which couples with a power tool handle 120 at the battery pack receptacle 130. The battery pack 300 further includes a lower portion 310 of a battery cell housing and an upper portion 320 of the battery cell housing. The battery pack 300 includes terminals 330. The terminals are electrically connected to the battery cells (such as a plurality of battery cells 315 shown in FIG. 4). The terminals 330 are configured to couple with the power tool 100 when the battery pack 300 is coupled within the battery pack receptacle 130. The battery pack housing 110 includes a locking mechanism 340 which includes a button 350 on the outside of the battery pack housing 110. When the battery pack 300 is connected to the battery pack receptacle 130, the locking mechanism 340 couples to the battery pack receptacle 130. The locking mechanism 340 prevents disconnection of the battery pack 300 when coupled to the battery pack receptacle 130. When the button 350 is pressed, the locking mechanism 340 is disconnected from the battery pack receptacle 130 allowing the battery pack 300 to be removed.

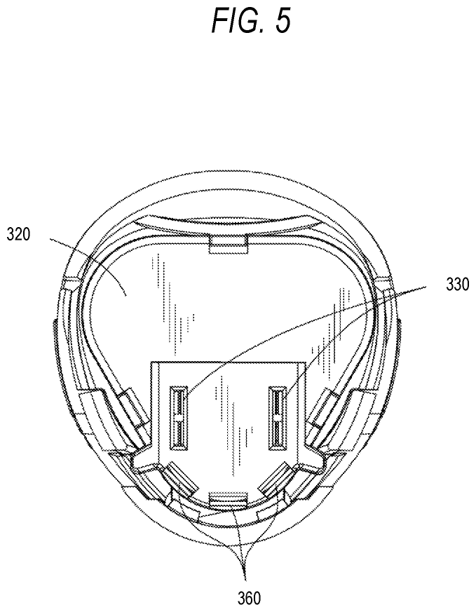

With reference to FIGS. 4 and 5, the battery pack 300 includes a plurality of battery cells 315, which are stored within a battery cell housing including the upper portion 320 and the lower portion 310. The upper portion 320 includes the battery pack terminals 330 and 360 which electrically couple to the plurality of battery cells 315. The upper portion 320 will electrically couple with the power tool 100 via the terminals 330 and 360. Once coupled, the battery pack 300 provides power to the power tool 100. The battery cell housing is attached within the battery pack housing 110. The lower portion 310 of the battery cell housing is coupled to the battery pack housing 110. The battery pack housing 110 includes the locking mechanism 340 and the button 350.

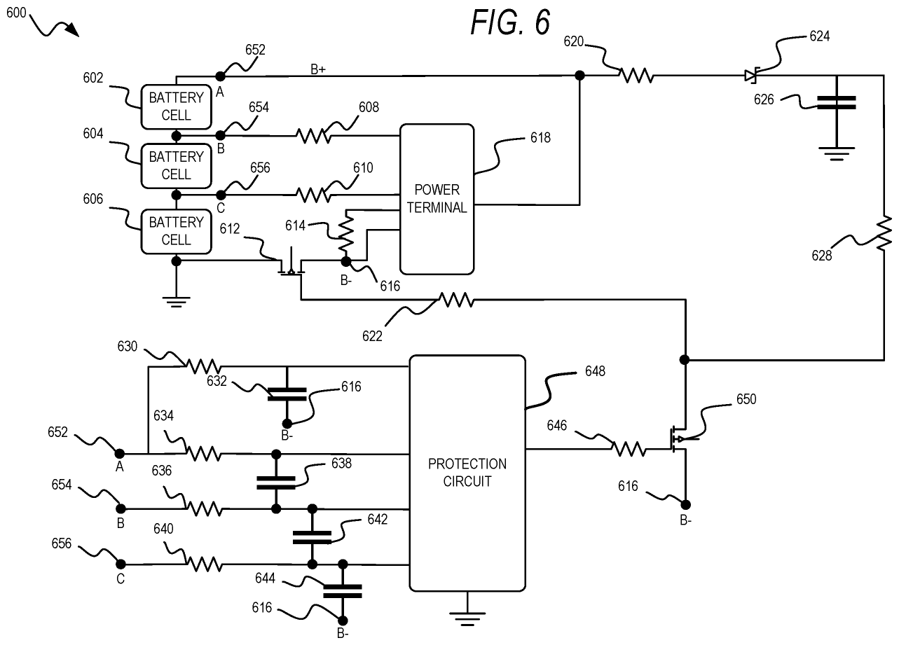

FIG. 6 illustrates a monitoring circuit 600 of the battery pack 300. In the example illustrated, the monitoring circuit includes battery cells 602, 604, and 606, a first resistor 608, a second resistor 610, a power switch 612, a third resistor 614, a battery negative terminal (“B−”) node reference point 616, power terminals 618, a fourth resistor 620, a fifth resistor 622, a diode 624, a first capacitor 626, a sixth resistor 628, a seventh resistor 630, a second capacitor 632, an eighth resistor 634, a ninth resistor 636, a third capacitor 638, a tenth resistor 640, a fourth capacitor 642, a fifth capacitor 644, an eleventh resistor 646, a protection circuit 648, and a signal switch 650. The battery cells 602, 604, and 606 correspond to the plurality of battery cells 315, shown in FIG. 4.

The battery cell 602 is connected between a B+ reference point and the battery cell 604. The B+ reference point shows the positive terminal of the plurality of battery cells 315. The battery cell 602 is connected to the power terminal 618 through the first resistor 608. The battery cell 602 is also connected to the fourth resistor 620. The fourth resistor 620 is connected in series with the diode 624 and the first capacitor 626. The third capacitor 638 is connected in series with the diode 624. The battery cell 604 is connected to the second resistor 610. The second resistor 610 is connected to the power terminals 618. The third resistor 614 is connected between the power terminals 618 and the B− node reference point 616. The battery cell 606 is connected to the power switch 612. The power switch 612 is connected between the signal switch 650, the power terminal 618, and the battery cells 602-606. The power switch 612 is also connected between a ground reference, and the B− node reference point 616. The B− node reference point 616 refers to the most negative terminal of the plurality of battery cells 602, 604, and 606.

The power switch 612 is connected to the fifth resistor 622. The signal switch 650 is connected between the fifth resistor 622 and the B− node reference point 616. The signal switch 650 is connected to the eleventh resistor 646. The eleventh resistor 646 is connected between the signal switch 650 and the protection circuit 648. The protection circuit receives input from a connection point A 652, a connection point B 654, and a connection point C 656. Connection point A 652 is connected to the seventh resistor 630, the second capacitor 632, and the eighth resistor 634. Connection point B is connected to the ninth resistor 636 and the third capacitor 638. The third capacitor 638 is connected between the eight resistor 634 and the ninth resistor 636. Connection point C is connected to the tenth resistor 640, the fourth capacitor 642, and the fifth capacitor 644. The fourth capacitor is connected to the B− node reference point 616. In some embodiments the power switch and the signal switch are field-effect transistors (“FETs”), such as a metal-oxide-semiconductor field-effect transistor (“MOSFET”).

The connection points A, B, and C are connected to receive the voltages of the battery cells 602, 604, and 606, respectively. The protection circuit 648 is configured to receive the voltages of the plurality of battery cells 602, 604, 606 as input signals. The protection circuit 648 is configured to compare each individual battery voltage to a predetermined voltage threshold (e.g., using a plurality of comparators or other hardware [e.g., not software-based control]). When the battery voltage of any of the battery cells 602, 604, 606 is greater than or equal to the predetermined voltage threshold, the protection circuit 648 will output a protection signal to the signal switch 650. In response to the protection signal, the signal switch 650 will be switched on. The power switch 612 will, in turn, switch off in response to the switching on of the signal switch 650. The off state of the power switch 612 prevents current flow to the plurality of battery cells 602, 604, 606. The on state of the power switch 612 permits current to pass from the power terminal 618 to the plurality of battery cells 602, 604, 606. While the power switch 612 is off, the battery cells 602, 604, 606 are prevented from being charged.

In some embodiments, the protection circuit 648 continuously receives voltage signals from the connection points A, B, and C. The protection circuit 648 continues to compare the battery voltage of each battery cell 602, 604, 606, to the predetermined voltage threshold. The protection circuit 648 will stop outputting the protection signal in response to the voltage of each of the battery cells 602, 604, 606 being less than the predetermined voltage threshold. The signal switch 650 will switch off in response to the voltages of each of the battery cells 602, 604, 606 being less than the predetermined voltage threshold. The power switch 612 will switch on in response to the signal switch 650 switching off. The on state of the power switch 612 allows the current to flow from the power terminal 618 to the plurality of battery cells 602, 604, 606 to charge the battery cells 602, 604, 606.

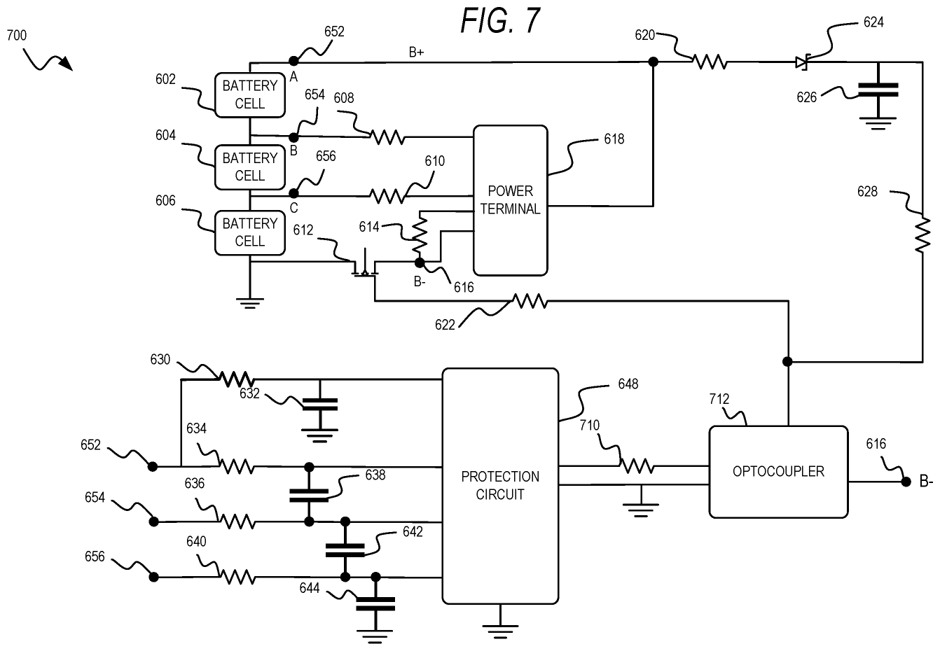

FIG. 7 illustrates a monitoring circuit 700 of the battery pack 300. As shown in FIG. 7, the protection circuit 648 is connected to a load resistor 710 and an optocoupler 712, instead of a signal switch (such as the signal switch 650 in FIG. 6). The optocoupler 712 is connected between the power switch 612 and the B-node reference point 616. The protection circuit 648, is configured to output the protection signal to the optocoupler 712 in response to any of the battery cell voltages from connection points A, B, and C exceeding the predetermine voltage threshold. In response to receiving the protection signal, the optocoupler 712 will turn on an internal LED to generate light that is detected by an internal photosensitive transistor, which is then turned on to create an isolated conductive path to the B-node reference point 616. Similar to the signal switch 650, the optocoupler 712 being turn on produces an electrical signal that is provided to the power switch 612. The power switch 612 will, in turn, switch off in response to the switching on of the optocoupler 712. The off state of the power switch 612 prevents current flow to the plurality of battery cells 602, 604, 606. The on state of the power switch 612 permits current to pass from the power terminal 618 to the plurality of battery cells 602, 604, 606. While the power switch 612 is off, the battery cells 602, 604, 606 are prevented from being charged.

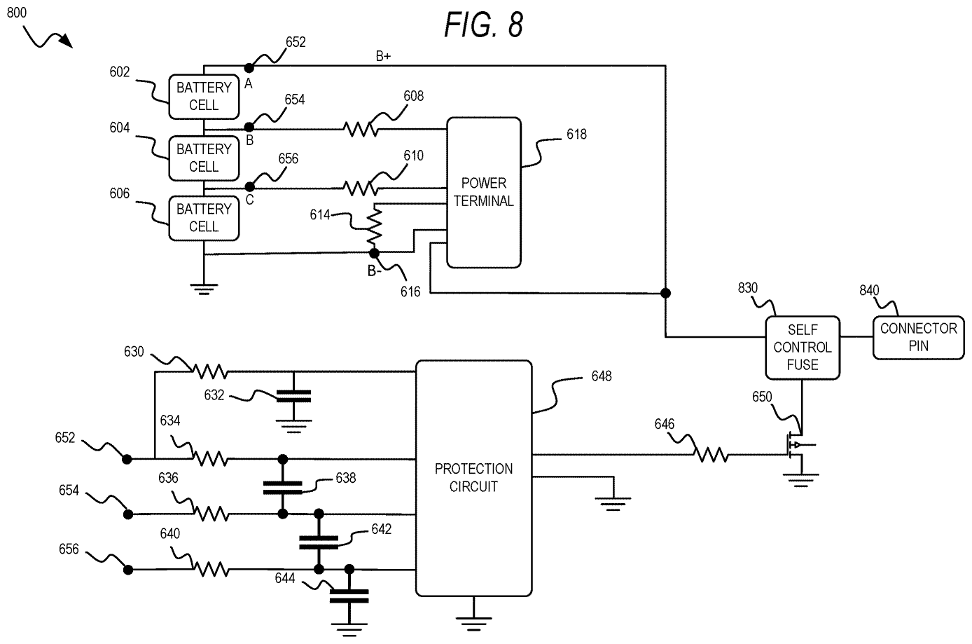

FIG. 8 illustrates a monitoring circuit 800 of the battery pack 300. In the example illustrated, the monitoring circuit includes the battery cells 602, 604, and 606, the first resistor 608, the second resistor 610, the third resistor 614, the battery negative terminal (“B−”) node reference point 616, power terminals 618, the seventh resistor 630, the second capacitor 632, the eighth resistor 634, the ninth resistor 636, the third capacitor 638, the tenth resistor 640, the fourth capacitor 642, the fifth capacitor 644, the eleventh resistor 646, the protection circuit 648, and the signal switch 650.

The battery cell 602 is connected between a B+reference point and the battery cell 604. The B+ reference point shows the positive terminal of the plurality of battery cells 315. The battery cell 604 is connected to the power terminal 618, through the first resistor 608. The battery cell 604 is connected to the second resistor 610. The second resistor 610 is connected to the power terminals 618. The third resistor 614 is connected between the power terminals 618 and the B− node reference point 616. The power terminal 618 is connected to a self-control fuse 830. The self-control fuse 830 is connected between a connector pin 840 and the signal switch 650. In some embodiments, the connector pin is a charging (“CH+”) pin. In some embodiments, the charging pin is a third terminal 330 of the battery pack 300. The connector pin 840 is connected to the battery cells 602, 604, and 606 through the self-control fuse 830 as a power delivery pin for charging the battery cells 602, 604, 606.

The connection points A, B, and C are connected to receive the voltages of the battery cells 602, 604, and 606, respectively. The protection circuit 648 is configured to receive the voltages of the plurality of battery cells 602, 604, 606 as input signals. When the battery voltage of at least one of the battery cells 602, 604, 606 is greater than or equal to the predetermined voltage threshold, the protection circuit 648 will output a protection signal to the signal switch 650. In response to the protection signal, the signal switch 650 will be switched on. The signal switch 650 will output a switch signal to the self-control fuse 830. The self-control fuse 830 will heat up in response to being pulled to ground and eventually overload (i.e., the fuse opens). In some embodiments, the self-control fuse 830 is a one-time, non-resettable fuse. In such embodiments, the battery cells 602, 604, 606 can continue to be charged by virtue of the positive (B+) and negative (B−) terminals of the battery pack 300. In other embodiments, the self-control fuse 830 is a resettable fuse. The overloaded self-control fuse 830 will disconnect the connector pin 840 from the battery cells 602, 604, 606. In response, the connector pin 840 will no longer be able to be used to charge the battery cells 602, 604, 606 (unless the self-control fuse 830 is resettable).

In some embodiments, the protection circuit 648 continues to compare the battery voltage of each battery cell 602, 604, 606, to the predetermined voltage threshold. The protection circuit 648 will stop outputting the protection signal in response to the voltage of each of the battery cells 602, 604, 606 being less than the predetermined voltage threshold. The signal switch 650 will switch off in response to the voltages of each of the battery cells 602, 604, 606 being less than the predetermined voltage threshold. In some embodiments, a resettable self-control fuse will reset to its original state and automatically reconnect the connector pin 840 to the battery cells 602, 604, and 606.

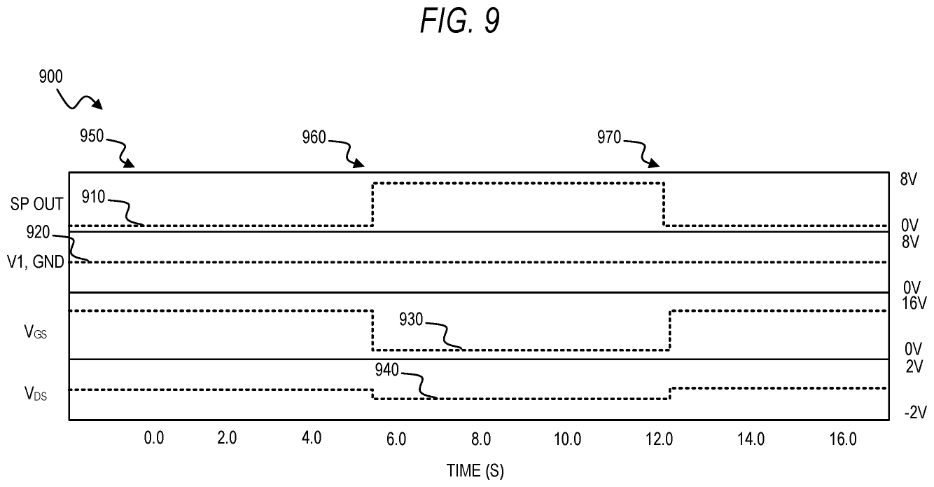

FIG. 9 illustrates a timing diagram 900 depicting the power tool 100 performance over a period of time. The horizontal axis of the time diagram depicts time, starting at 0 seconds denoted with the T mark 950. The vertical axis displays various voltage signals of the battery pack 300. The voltages include a protection signal 910 output by the protection circuit 648, a voltage V1 820 that represents a voltage of one of the battery cells 602, 604, 606, a voltage Vgs 930 that represents a total stack voltage of the battery pack 300 when the protection circuit is not outputting the protection signal, and a voltage Vds 940. The vertical axis displays voltage starting from −2 volts to 6 volts. At time position 960, the protection circuit 648 detects a voltage higher than the predetermined voltage threshold. In some embodiments, the predetermined voltage threshold is 4.3 volts. The protection circuit 648 determines the voltage of V1 920 to be 4.32 volts. The protection circuit 648 outputs the protection signal. In this embodiment, the protection signal is an active high signal with a voltage of, for example, 7.3 volts. The protection signal turns off the power switch 612 to isolate the battery cells 602, 604, and 606 as described previously with respect to FIG. 6. The protection circuit 648 continues to monitor the voltage of the battery cells 602, 604, and 606. At time 970, the protection circuit 648 detects that the voltage of V1 920 is below the predetermined voltage threshold. In response, the protection circuit 648 ceases outputting the protection signal. The timing diagram 900 illustrates at time 970 the protection signal being reduced to 0 volts.

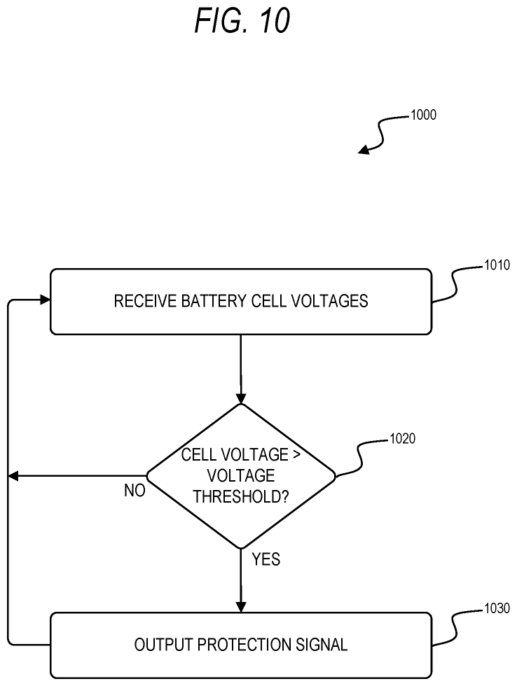

FIG. 10 is a flow chart illustrating a method 1000 for determining overcharge conditions of a battery pack. The method 1000 is performed by the protection circuit 648 (shown in FIGS. 6, 7 and 8). The method 1000 includes receiving voltages of a plurality of cells, such as battery cells 602, 604, and 606 (shown in FIGS. 6, 7 and 8) at step 1010. The protection circuit 648 will receive the voltage signals inputs from connection points A, B, and C. The method 1000 includes comparing the received voltages to a predetermined voltage threshold at step 1020. The protection circuit 648 will compare the voltage from each connection point individually to the predetermined threshold. In some embodiments, the predetermined threshold is set to 4.3 volts. The method 1000 includes outputting a protection signal when the voltage of any of the battery cells 602, 604, 606 is greater than the predetermined voltage threshold at step 1030. In some embodiments, the protection circuit 648 will output the protection signal to a signal switch 650 shown in FIGS. 6 and 8. In other embodiments, the protection circuit 648 will output the protection signal to an optocoupler 712 shown in FIG. 7.

Thus, embodiments described herein provide, among other things, a battery pack including an overcharge protection circuit. Various features and advantages are set forth in the following claims.

What is claimed is:

1. A battery pack comprising:
a plurality of battery cells;
a protection circuit connected to the plurality of battery cells, the protection circuit configured to:
monitor a voltage of each of the plurality of battery cells,
compare the voltage of each of the plurality of battery cells to a threshold voltage, and
output a protection signal in response to the voltage of at least one of the plurality of battery cells being greater than or equal to the threshold voltage;
a first switch connected to the protection circuit, the first switch configured to receive the protection signal; and
a second switch connected to the first switch and the plurality of battery cells,
wherein a conductive state of the second switch is controlled by the first switch.

2. The battery pack of claim 1, wherein the first switch is configured to be switched ON in response to receiving the protection signal.

3. The battery pack of claim 2, wherein the second switch is configured to be switched OFF in response to the first switch being switched ON.

4. The battery pack of claim 3, wherein, when the second switch is switched OFF, the second switch prevents charging of the plurality of battery cells.

5. The battery pack of claim 1, wherein the first switch is configured to be switched OFF in response to the protection circuit not outputting the protection signal.

6. The battery pack of claim 5, wherein the protection circuit is configured to not output the protection signal when the voltage of each of the plurality of battery cells is less than the threshold voltage.

7. The battery pack of claim 1, wherein the first switch is connected between the plurality of battery cells and a power terminal of the battery pack.

8. The battery pack of claim 7, wherein, when the first switch is switched ON, charging current is permitted to pass from the power terminal of the battery pack to the plurality of battery cells.

9. A battery pack comprising:
a plurality of battery cells;
a protection circuit connected to the plurality of battery cells, the protection circuit configured to:
monitor a voltage of each of the plurality of battery cells,
compare the voltage of each of the plurality of battery cells to a threshold voltage, and
output a protection signal in response to the voltage of at least one of the plurality of battery cells being greater than or equal to the threshold voltage;
a switch connected to the protection circuit, the switch configured to receive the protection signal; and
a fuse connected to the switch and the plurality of battery cells,
wherein the fuse is controlled by the switch.

10. The battery pack of claim 9, wherein the fuse is further connected to a connector terminal, wherein the connector terminal is configured to provide charging current to the plurality of battery cells.

11. The battery pack of claim 10, wherein the connector terminal is a charge terminal of the battery pack.

12. The battery pack of claim 11, wherein the charge terminal is disconnected from the plurality of battery cells when the fuse is opened.

13. The battery pack of claim 12, wherein the fuse is a resettable fuse.

14. The battery pack of claim 12, wherein the fuse is a one-time, non-resettable fuse.

15. The battery pack of claim 9, wherein the switch is configured to be switched ON in response to the protection circuit outputting the protection signal.

16. The battery pack of claim 15, wherein the protection circuit is configured to not output the protection signal when the voltage of each of the plurality of battery cells is less than the threshold voltage.

17. A battery pack comprising:
a plurality of battery cells;
a protection circuit connected to the plurality of battery cells, the protection circuit configured to:
monitor a voltage of each of the plurality of battery cells,
compare the voltage of each of the plurality of battery cells to a threshold voltage, and
output a protection signal in response to the voltage of at least one of the plurality of battery cells being greater than or equal to the threshold voltage;
an optocoupler connected to the protection circuit, the optocoupler configured to receive the protection signal; and
a switch connected to the optocoupler and the plurality of battery cells,
wherein a conductive state of the switch is controlled by the optocoupler.

18. The battery pack of claim 17, wherein the switch is configured to be switched OFF when the optocoupler receives the protection signal.

19. The battery pack of claim 17, wherein the switch is configured to be switched ON in response to the protection circuit not outputting the protection signal.

20. The battery pack of claim 19, wherein the protection circuit is configured to not output the protection signal when the voltage of each of the plurality of battery cells is less than the threshold voltage.
